(19) United States
(12) Patent Application Publication
(10) Pub. No.: US 2026/0104602 A1
(43) Pub. Date: Apr. 16, 2026

(54) Optical Transmitter

(71) Applicant: NTT, Inc., Tokyo (JP)

(72) Inventors: Josuke Ozaki, Musashino-shi, Tokyo (JP); Yoshihiro Ogiso, Musashino-shi, Tokyo (JP); Mitsuteru Ishikawa, Musashino-shi, Tokyo (JP)

(21) Appl. No.: 19/115,384

(22) PCT Filed: Oct. 3, 2022
(86) PCT No.: PCT/JP2022/037031

§ 371 Date: Mar. 26, 2025

(51) Int. Cl. G02F 1/01; G02F 1/015; H05K 7/20

(52) U.S. Cl. CPC G02F 1/0102; G02F 1/015; H05K 7/2039

(57) ABSTRACT

Disclosed is a new configuration for improving temperature dependency of optical modulation output characteristics, and an implementation form adapted to each configuration in an optical transmitter in which an optical modulator and a driver IC thereof are integrally packaged. The optical transmitter includes: an optical modulator; a driver IC for supplying a modulation electrical signal for the optical modulator; a first Peltier device for controlling a temperature of the optical modulator; a second Peltier device for controlling a temperature of the driver IC; and a subcarrier including an electrical wiring between the optical modulator and the driver IC and being mounted on the first Peltier device and the second Peltier device. The chip of the optical modulator and the driver IC are flip-chip mounted face down, and the temperature of the second Peltier device is set to be lower than the temperature of the first Peltier device.

### TECHNICAL FIELD

The present invention relates to an optical transmitter used in optical communication. More particularly, the present invention relates to an implementation form of an optical transmitter including a semiconductor optical modulator and a driver IC thereof.

### Background Art

In order to cope with a rapid traffic increase of a communication network, digital coherent optical transmission combining a coherent communication scheme and a digital signal processing technology has been introduced into an optical fiber communications system. Starting from the establishment of a backbone network transmission technology of 100 Gbps per wavelength at the beginning, transmission of 400 Gbps to 600 Gbps per wavelength, which is faster, has been put into practical use at present.

In the above-described digital coherent optical transmission, an optical transmission/reception device in which an optical receiver and an optical transmitter are integrated is used. In the optical transmission/reception device of a system having a transmission capacity exceeding 400 Gbps, an analog component such as a radio frequency (RF) electric circuit is required to have a wide bandwidth. For example, in an optical modulator, a modulation bandwidth of 40 GHz or more is required. In order to reduce a high-frequency loss and downsize a device, which leads to having a wide bandwidth, for example, a form in which an RF driver IC and an optical modulator are mounted in an integrated package on a transmission side has attracted attention. An implementation form of this optical transmitter is also standardized by the Optical Internetworking Forum (OIF) under the name of High-Bandwidth Coherent Driver Modulator (HB-CDM) (Non Patent Literature 1). On a reception side of the optical transmission/reception device, a transimpedance amplifier (TIA) and an optical receiver are mounted in an integrated package, which is also referred to as an integrated coherent receiver (ICR).

Turning to materials for an optical transmitter/receiver device, a semiconductor-based optical modulator has attracted attention instead of a conventional lithium niobate (LN) optical modulator in terms of miniaturization and cost reduction. For higher-speed modulation operation, a compound semiconductor represented by InP is mainly used. Furthermore, research and development are concentrated on a Si-based optical device in a system with emphasis on miniaturization and cost reduction.

There are advantages and disadvantages inherent to materials in the above-described semiconductor-based optical modulator, and for example, in an InP optical modulator, temperature control of an optical modulator chip is essential during operation in order to control a band-edge absorption effect. On the other hand, the Si optical modulator has a merit that the temperature control is unnecessary, but has a smaller electro-optical effect than other material systems. For this reason, it is necessary to increase the electro-optical interaction length, and as a result of increasing the device length, a high-frequency loss may be increased. There are many problems in achieving the higher speed and wide bandwidth of the optical modulator in addition to the implementation technology for the wide bandwidth and miniaturization.

The operation temperature (case temperature) of the optical transmitter with the HB-CDM is required to be in a range of at least −5° C. to 75° C. In order to obtain the operation temperature, generally, only the optical modulator chip is mounted on a Peltier device in consideration of power consumption (Patent Literature 1).

### CITATION LIST

### Patent Literature

Patent Literature 1: WO 2021/171599 A

### Non Patent Literature

Non Patent Literature 1: OIF, Implementation Agreement for the High Bandwidth Coherent Driver Modulator (HB-CDM), [online], Jul. 15, 2021, [retrieved on Sept. 1, 2022], Internet <URL:https://www.oiforum.com/wp-content/uploads/OIF-HB-CDM-02.0.pdf>

Non Patent Literature 2: J. Ozaki et al., “500-Gb/s/2 Operation of Ultra-Low Power and Low-Temperature-Dependence InP-Based High-Bandwidth Coherent Driver Modulator,” in Journal of Lightwave Technology, vol. 38, no. 18, pp. 5086-5091, 15 Sept. 15, 2020, doi: 10.1109/JLT.2020.2998466.

### SUMMARY OF INVENTION

### Technical Problem

However, in the optical transmitter of the related art, deterioration of high-frequency characteristics of the driver IC at a high temperature has been a problem. Specifically, in a case where the environmental temperature is high, there has been a problem that the high frequency bandwidth, peaking amount, and gain of the driver IC deteriorate. In achieving the speed increase and wide bandwidth of the optical transmitter, the influence of a decrease in signal quality due to the above-described deterioration cannot be ignored. Therefore, an optical transmitter capable of maintaining a constant high-frequency characteristics regardless of a change in an environmental temperature is desired.

In view of the above-described problems, the present invention provides a novel configuration and an implementation form of an optical transmitter that suppresses temperature dependency of an optical transmitter including a driver IC, is excellent in speed, and is capable of stably operating regardless of the environmental temperature.

### Solution to Problem

According to one aspect of the present invention, there is an optical transmitter including: an optical modulator; a driver integrated circuit (driver IC) for supplying a modulation electrical signal for the optical modulator; a first Peltier device for controlling a temperature of the optical modulator; a second Peltier device for controlling a temperature of the driver IC; and a subcarrier that includes an electrical wiring between the optical modulator and the driver IC and is mounted on the first Peltier device and the second Peltier device, in which a chip of the optical modulator and the driver IC are flip-chip mounted face down, and the temperature of the second Peltier device is set to be lower than the temperature of the first Peltier device.

### Advantageous Effects of Invention

In view of the above-described problems, the present invention provides a novel configuration and an implementation form of an optical transmitter that suppresses temperature dependency of an optical transmitter including a driver IC, is excellent in speed, and is capable of stably operating regardless of the environmental temperature.

### BRIEF DESCRIPTION OF DRAWINGS

FIG. 1 is a side cross-sectional view illustrating an implementation form of an optical transmitter using an HB-CDM of the related art.

FIG. 2 is a side cross-sectional view illustrating an implementation form of an optical transmitter using an HB-CDM of the present invention.

FIG. 3 is a diagram for describing a restriction of a wire connection portion in a height direction in an optical transmitter.

FIG. 4 is a top view illustrating a modified implementation form of an optical transmitter of the present invention.

FIG. 5 is a side cross-sectional view illustrating another implementation form of an optical transmitter of the present invention.

FIG. 6 is a side cross-sectional view illustrating still another implementation form of an optical transmitter of the present invention.

FIG. 7 is a diagram for describing density arrangement of a Peltier device in an optical transmitter of the present invention.

### Description of Embodiments

The present invention presents a new configuration for improving temperature dependency of high-frequency characteristics of an optical transmitter, and an implementation form adapted to each configuration in an optical transmitter in which an optical modulator and a driver IC thereof are integrally packaged. The configuration for improving the temperature dependency includes a new application form of a temperature regulator (thermoelectric cooler (TEC)) in the optical transmitter. Moreover, various implementation forms of a driver IC, an optical modulator chip and a spatial optical component, which are adapted to a new application form of the TEC are also proposed.

The TEC is also called a thermoelectric cooler, and is known as a small cooling device by Peltier junction. The TEC includes an n-type semiconductor, a p-type semiconductor, and a metal, and when a direct current flows through both surfaces of an element formed in a plate shape, heat absorption occurs on one surface and heat dissipation occurs on the other surface. When the direction of the current is reversed, the heat absorption and the heat dissipation are switched. Therefore, local and accurate temperature control for the IC and the electronic component is possible. In the following description, the temperature regulator is referred to as a TEC for simplicity, and will be described as a Peltier device. As long as the temperature of the driver IC or the optical modulator chip can be controlled, the present invention is not limited to the Peltier device.

In the following, the problem of the temperature dependency of the high-frequency characteristics in the optical transmitter will be first described with an optical modulator using the HB-CDM of the related art as an example. Thereafter, a novel configuration for improving the temperature dependency of the high-frequency characteristics with the optical transmitter of the present invention will be described together with various implementation forms.

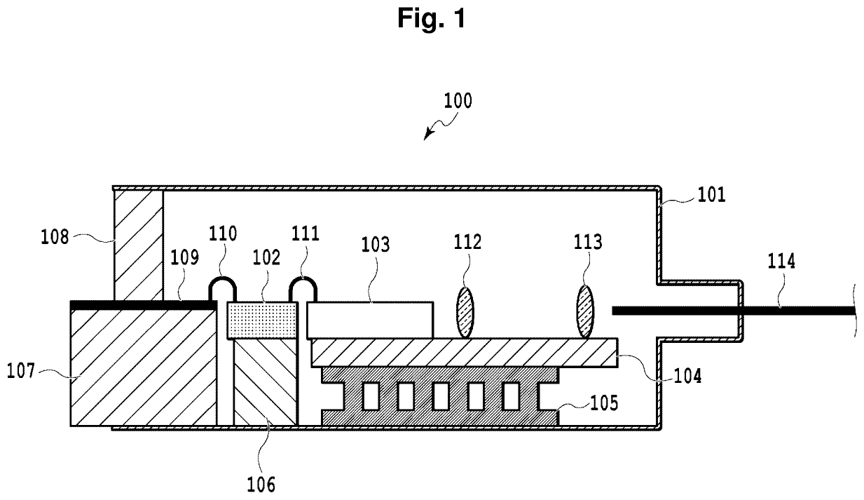

FIG. 1 is a side cross-sectional view illustrating an implementation form of the optical transmitter using the HB-CDM of the related art. In an optical transmitter 100, a driver IC 102, an optical modulator chip 103, lenses 112 and 113 which are spatial optical components, and the like are housed inside a package housing 101 made of ceramic, metal, or the like, or a combination thereof, according to the specification of the HB-CDM. More specifically, the optical modulator chip 103 is mounted on the bottom surface inside the housing 101 via a subcarrier 104 on a Peltier device 105. At the right end of the optical modulator chip 103 in the drawing, there is an emission end face of the modulation light, and the lenses 112 and 113 for optically coupling the modulation light with an optical fiber 114 are also mounted on the subcarrier.

The driver IC 102 is mounted on a metal block or a ceramic member 106 adjacent to the optical modulator chip 103. Moreover, a wiring board base 107 and a package wall surface 108 are provided as wall surfaces on the left side of the package housing 101 in the drawing, and define the outside and the internal space of the optical transmitter together with the package housing 101. The optical transmitter 100 can be configured such that the entire package ensures airtightness.

A modulation electrical signal supplied from an external digital signal processor (DSP) is supplied to the optical modulator chip 103 via a wiring layer 109 of the wiring board base 107 and the driver IC 102. The wiring layer 109 and the driver IC 102, and the driver IC 102 and the optical modulator chip 103 are connected by gold wire lines 110 and 111, respectively. In a case of the polarization multiplexing type IQ optical modulation scheme, the modulation electrical signal includes an I channel and a Q channel for X polarization and Y polarization. In a case where one channel is supplied as a differential signaling electrical signal, at least eight signal wirings and a GND wiring are required for one optical modulator, but the modulation signaling is not limited thereto. As described in Patent Literature 1, the optical transmitter 100 illustrated in FIG. 1 is mounted on a common device substrate together with an ICR package or a DSP in which the TIA and the optical receiver on the reception side are integrated, and can constitute an optical transmission/reception device.

Here, attention is again focused on the Peltier device 105 in the optical transmitter. Temperature control is essential for the optical modulator chip 103 prepared on an InP substrate, and the temperature is controlled to a predetermined operation temperature by the Peltier device 105. As illustrated in FIG. 1, the Peltier device 105 has a size that covers at least the entire region of the optical modulator chip 103, and its position may overlap a region of the spatial optical component such as a lens. On the other hand, in the optical transmitter 100 of the related art, it is considered that the temperature control of the driver IC 102 is not necessary, and the optical transmitter is fixed in the package by a member 106 such as a metal block or a ceramic member. When the external temperature (environmental temperature) of the optical transmitter 100 increases, the increased temperature becomes the operation temperature of the driver IC 102. Actually, since the driver IC is also a heating element, in consideration of heat generation from the driver, it is estimated that the operation temperature of the driver IC is higher than the external temperature by about +5° C. to 10° C. When the maximum environmental temperature at which the optical transmission/reception device including the optical transmitter is used is 85° C., the temperature of the driver IC 102 itself is at least 85° C. or higher. The driver IC also has large power consumption, and the driver IC itself generates heat. This means that the back side temperature of the driver IC exceeds the maximum environmental temperature of 85° C. due to the influence of heat generation of the driver IC.

The driver IC has temperature dependency of amplification characteristics (high-frequency characteristics) of a radio frequency electrical signal, and in a high temperature state, a high frequency bandwidth tends to decrease as compared with a room temperature state. Conversely, in a low temperature state, the high frequency bandwidth tends to increase as compared with the room temperature state. As described above, the high-frequency characteristics of the driver IC are different between the low temperature state and the high temperature state. The modulation signal supplied to the driver IC is variously optimized and compensated by the DSP in the room temperature state. However, performing such compensation while dynamically performing update with temperature variation is complicated processing and is not generally performed. Since the operation is continued in a constant compensation state at the room temperature, the compensation state of the modulation signal deviates from the optimum point when the state changes to the low temperature state or the high temperature state. Therefore, optical transmission characteristics and waveform quality of the optical transmitter fluctuate or deteriorate.

The IQ modulator of the optical modulator chip 103 is a linear modulator that preserves the amplitude and phase of the electrical signal, and variations in the level and waveform quality of the modulation electrical signal directly affect the quality of the modulation output light. When the external temperature changes during the operation of the optical transmitter, the optical modulator chip itself is maintained at a constant temperature since the temperature is controlled by the Peltier device, but the operation temperature of the driver IC changes.

As a result, there is also a problem that a level variation and a quality variation of the modulation light of the HB-CDM occur, and since the environmental temperature temporally changes, transmission characteristics are deteriorated and are not stable.

The characteristic deterioration caused by the environmental temperature on the high-frequency band of the electrical signal causes waveform distortion of the modulation signal, and the modulation accuracy of the modulation output light from the optical modulator is deteriorated. In the optical receiver that receives such deteriorated modulation light, a BER floor appears in BER characteristics, which leads to deterioration of transmission characteristics of a system.

The influence of deterioration of the high-frequency characteristics of the driver IC at high temperature as described above cannot be ignored in a situation where a modulation bandwidth of 40 GHz or more is required as the request for widening the bandwidth of the modulation electrical signal is made. The present invention presents a new configuration and an implementation form for improving temperature dependency in high-frequency characteristics and optical transmission characteristics in the optical transmitter in which the optical modulator and the driver IC thereof are integrally packaged.

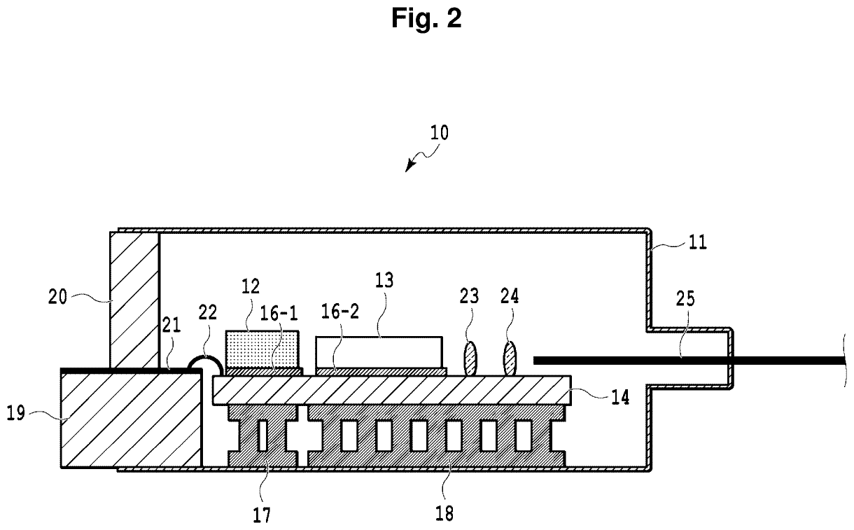

FIG. 2 is a side cross-sectional view illustrating an implementation form of the optical transmitter using the HB-CDM of the present invention. In an optical transmitter 10 of the present invention, similarly to the configuration of the related art illustrated in FIG. 1, an optical modulator chip 13 made of InP, a driver IC 12 thereof, and the like are integrated in a package housing 11 for the HB-CDM. A wiring board base 19 and a package wall surface 20 are provided as wall surfaces on the left side of the package housing 11 in the drawing, and the inside and the outside of the package are defined similarly to FIG. 1. A difference from the configuration of the related art in FIG. 1 is an application form of the TEC that performs temperature control, that is, the Peltier device. Unlike the application form of the Peltier device in FIG. 1, the driver IC 12 is also mounted on a Peltier device 17. The Peltier device 17 of the driver IC 12 is separate and independent from a Peltier device 18 that performs temperature control of the optical modulator chip 13, and the optical transmitter 10 includes two Peltier devices.

On the two Peltier devices 17 and 18, the driver IC 12 is mounted at a position corresponding to the Peltier device 17 via a single subcarrier 14, and the optical modulator chip 13 and lenses 23 and 24 are mounted at a position corresponding to the Peltier device 18. The subcarrier 14 functions as a base for flip-chip mounting the optical modulator chip 13 and the driver IC 12 across the two Peltier devices 17 and 18. Therefore, the heights of the two Peltier devices 17 and 18 need to be uniform such that the subcarrier is not slantingly mounted. On the subcarrier 14, the optical modulator chip 13 and the driver IC 12 are flip-chip mounted face down using an Au pillar/bump, a Cu pillar/bump, or the like. For face-down mounting, the driver IC 12 and the optical modulator chip 13 are mounted with respective electrode pad surfaces facing downward in the drawing, that is, facing the upper surface of the subcarrier 14. Furthermore, all the spatial optical components such as the lenses 23 and 24 are also mounted on the subcarrier 14 and disposed in the region of the Peltier device 18.

In order to prevent the members to be mounted from being inclined when the flip-chip mounting is performed, it is very important to control the flatness of the surface of the subcarrier 14 on which the members are mounted. For example, the flatness of the upper surface side of the subcarrier 14 on which the members are mounted needs to be 0.05 mm or less. Underfill materials 16-1 and 16-2 having excellent thermal conductivity can be embedded between the flip-chip mounted driver IC 12 and optical modulator chip 13 and the subcarrier 14 in order to perform temperature control by the Peltier device. In order to effectively control the driver IC 12 and the optical modulator chip 13 by using the two Peltier devices 17 and 18, an underfill material having thermal conductivity of 3 W/mK or more is desirable. Introduction of the underfill materials 16-1 and 16-2 is also very effective in increasing the bonding strength with the subcarrier 14.

The configuration without the above-described underfill material may be adopted. Since the underfill material is a dielectric with a constant dielectric constant and dielectric loss tangent, it may lead to loss of a high frequency wiring of the optical modulator. It should be noted that, depending on a high frequency bandwidth and a baud rate required for the optical modulator, there may be a configuration in which high-frequency characteristics are prioritized over temperature stability and bonding strength, and the underfill material is not used.

On the subcarrier 14, a wiring for connection with the DC wiring of the driver IC 12 and the DC wiring of the optical modulator chip 13, an RF line for high-frequency connection between the driver IC 12 and the optical modulator chip 13, a positioning marker for mounting the spatial optical component, and the like are formed by a metal pattern.

Since the temperature control by the two Peltier devices 17 and 18 is performed across the subcarrier 14, and in consideration of mounting the driver IC 12 having a large heat generation amount, it is desirable to use a material having as excellent thermal conductivity as possible for the subcarrier 14. Specifically, a ceramic substrate such as an AlN substrate is preferable. Since the AlN substrate has a material constant close to that of InP, the AlN substrate is compatible with the optical modulator using InP also in terms of behavior with respect to temperature change. From the same reason and the viewpoint of material consistency, it is desirable that the ceramic member on the upper surface of the Peltier device 17 is also composed of AlN.

In FIG. 2, the subcarrier 14 is illustrated as being composed of AlN having a one-layer structure, but may be a multilayer AlN substrate. In a case where the number of DC wirings provided to the optical modulator is large, or in a case where it is necessary to perform cross wiring for switching the order of terminals, it is possible to make a flexible element/wiring layout using a multilayer wiring by using the multilayer substrate. Also from the viewpoint of RF design, by forming the subcarrier 14 as a multilayer wiring, a GND layer can be provided adjacent to the wiring layer, high-density wiring can be performed by further reducing a line width, and the degree of freedom in layout can be increased.

All the spatial optical components such as the lenses 23 and 24 are mounted on the Peltier device 17 in order to suppress the thickness variation of an adhesive due to a temperature change. Thus, it is possible to minimize fluctuation of the optical insertion loss and the like caused by the deviation of the optical axis due to the temperature change. Note that examples of the spatial optical component include a fiber fixing member, and a polarization beam combiner (PBC).

Since the face-down mounting is performed in the optical transmitter 10 of the present invention in FIG. 2, it is necessary to consider optical coupling with an optical fiber 25 in a case where a lens is mounted as the spatial optical component. Normally, a waveguide that emits the modulation output light of the optical modulator chip 13 is located close to the subcarrier 14 side in the height direction. Depending on the height of the waveguide from the lower surface of the optical modulator chip 13, the height of the Au/Cu pillar, and the size of the lens, it may be difficult to mount the lens. Such a case will be described later as another embodiment.

As described above, the driver IC is a heating element, and is not considered as an object to be temperature-controlled by the Peltier device. Driving power is required to operate the Peltier device, and it is not considered to use extra power for the heating element. However, in order to realize the wide bandwidth of the optical transmitter, the inventors have made a new idea of controlling the temperature of the heating element.

The optical transmitter 10 of the present invention includes the two Peltier devices 17 and 18 that are independently capable of being controlled as described above, such that the temperature of the optical modulator chip 13 and the temperature of the driver IC 12 can be independently controlled. Although not explicitly illustrated in FIG. 2, two Peltier devices are connected to separate control current sources. For a specific control temperature of each part, the InP optical modulator is desirably used generally at about 45±10° C. since the modulation efficiency decreases when the temperature is too low.

On the other hand, for the driver IC 12, it is known that the high-frequency characteristics are better in the low temperature state than in the high temperature state, and it is desirable as the set temperature is lower. However, even when the set temperature is too low, the improvement of the high-frequency characteristics of the driver IC is limited while the power consumption in the Peltier device is increased. Therefore, for example, it is most appropriate to operate the driver IC at 30±10° C. near room temperature from the viewpoint of achieving both power consumption and high-frequency characteristics. By independently setting the optical modulator chip 13 and the driver IC 12 to different temperatures, it is possible to realize an optical transmitter that can operate in an optimum state for each of the optical modulator chip 13 and the driver IC 12.

Therefore, the optical transmitter 10 of the present invention includes an optical modulator 13, a driver integrated circuit (driver IC) 12 for supplying a modulation electrical signal for the optical modulator, a first Peltier device 18 for controlling a temperature of the optical modulator, a second Peltier device 17 for controlling a temperature of the driver IC, and a subcarrier 14 including an electrical wiring between the optical modulator and the driver IC and being mounted on the first Peltier device and the second Peltier device, and can be implemented as an optical transmitter such that the chip of the optical modulator and the driver IC are flip-chip mounted face down, and the temperature of the second Peltier device is set to be lower than the temperature of the first Peltier device.

Between the two Peltier devices 17 and 18 and the subcarrier 14, it is necessary to mount a conductive paste or solder having thermal conductivity of 30 W/mK or more and excellent thermal conductivity in order to improve heat dissipation by the Peltier device. For the management of the manufacturing process temperature and the like of a module, the same conductive paste and solder may be used, or those having different fixing temperatures and the like may be used in combination.

In the optical transmitter 10 of FIG. 2, the two Peltier devices 17 and 18 control the temperature of the driver IC and the temperature of the optical modulator chip via the common subcarrier 14. Since the driver IC and the optical modulator chip are connected via the subcarrier 14, the temperature of the driver IC and the temperature of the optical modulator chip cannot be completely independently controlled. However, the Peltier device 17 can significantly prevent the temperature of the driver IC 12 from being high and improve the high-frequency characteristics. Furthermore, by using the single subcarrier 14, the member cost can be suppressed and the mounting process can be simplified. For example, in order to realize the independent control, as described later, it is also effective to provide a groove for thermal separation on one of the upper surface and the lower surface of the subcarrier 14 or on both the upper surface and the lower surface to realize thermal separation between the optical modulator and the driver IC.

Although FIG. 2 illustrates the optical transmitter 10 using the HB-CDM as an example, the same effect can be obtained even in the case of using other package forms as long as an optical transmission module is constituted in which the driver IC and the optical modulator are integrally configured. Furthermore, FIG. 2 illustrates an example in which a wiring from a DSP that supplies a modulation signal to the driver IC 12 is connected on the RF terrace by a flexible printed circuit (FPC). That is, a metal pattern 21 on the upper surface of the wiring board base 19 outside the optical transmitter is connected to an FPC cable (not illustrated). Since a FPC interface does not require an RF via (VIA) or the like as compared with a configuration using a surface mount technology (SMT), the FPC interface is excellent in high-frequency characteristics.

Next, a high-frequency mounting structure for ensuring high-frequency characteristics of the optical transmitter including the driver IC and the optical modulator will be described. In the optical transmitter 10 using the HB-CDM illustrated in FIG. 2, the electrode pad of the driver IC and the electrode pad of the optical modulator are connected by the high frequency wiring of the subcarrier 14, and the driver IC 12 and the optical modulator chip 13 are flip-chip mounted using the Au pillar or the Cu pillar. On the other hand, since it is difficult to connect the electrode pad of the driver IC and the electrode pad of the RF terrace by flip-chip mounting, the electrode pads are connected by a wire 22.

In general, in the optical modulator, the inductance of the electrical signal path contributes most to the high-frequency characteristics. For example, when a wire is long, a series inductance component increases, and thus a roll-off frequency in the high-frequency characteristics shifts to the low-frequency side due to LC resonance. Therefore, in order to improve the high-frequency characteristics, it is desirable that the series inductance is low.

In the optical transmitter 10 of the present invention illustrated in FIG. 2, the flip-chip mounting is used for the driver IC and the optical modulator chip, and the inductance of the electrical signal path is suppressed to about ⅕ to 1/10 as compared with a normal wire connection, and the bandwidth can be widened. In the optical transmitter 10, the position of the wire connection portion in the height direction and the distance between the chips are further defined.

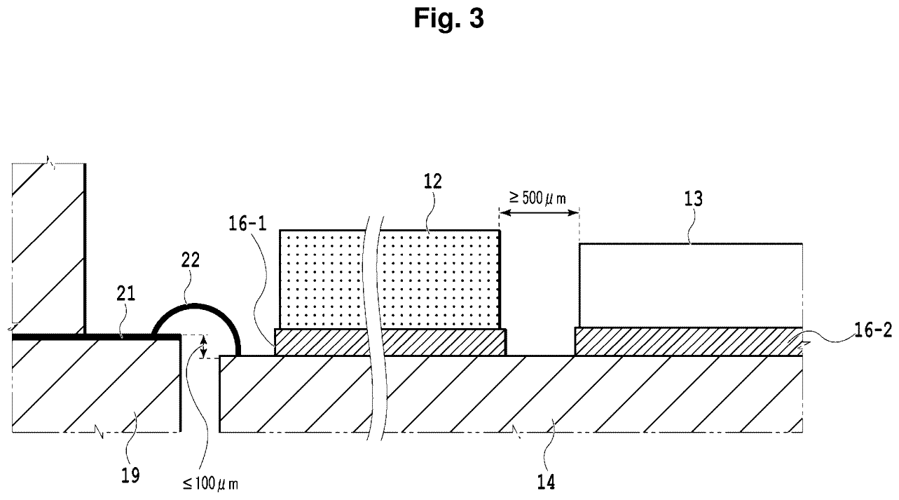

FIG. 3 is a diagram for describing a restriction of a wire connection portion in the height direction in the optical transmitter. The vicinity of the electrode 21 of the RF terrace and the vicinity of the upper surfaces of the driver IC 12 and optical modulator chip 13 in FIG. 2 are enlarged. It is desirable that the inductance between the electrode of the RF terrace and the electrode of the driver IC is as small as possible although the influence on the characteristics is small as compared with the inductance between the electrode of the driver IC and the electrode of the optical modulator. As illustrated in FIG. 3, it is desirable to adjust the height of each member such that the height difference between the upper surface of the electrode 21 of the RF terrace connected by the wire 22 and the subcarrier 14 is 100 μm or less. For example, the heights of the Peltier devices 17 and 18 may be changed, the thickness of the subcarrier 14 may be changed, or the height of the wiring board base 19 of the RF terrace may be changed.

In terms of the high-frequency characteristics, when the wiring becomes too long, the loss increases and the high-frequency characteristics deteriorate. Therefore, it is desirable that the distance between the driver IC and the optical modulator chip is as close as possible. On the other hand, when the driver IC and the optical modulator chip are too close to each other, thermal interference occurs between the two Peltier devices, heat from the driver IC is transmitted to the optical modulator, and the operation may become unstable. Therefore, the driver IC 12 and the optical modulator chip 13 need to be separated from each other by at least 500 μm or more. By ensuring a gap of 500 μm or more between the IC and the chip, the jig or the like can easily access the optical transmitter in the mounting process. In consideration of the deterioration of the high-frequency characteristics, it is necessary to suppress the distance between the driver IC 12 and the optical modulator chip 13 to 5 mm or less at the maximum.

In terms of driving efficiency of the driver IC, differential driving capable of suppressing amplitude is desirable as compared with single-end driving, and the modulation electrical signal corresponds to a differential signal interface from the driver to the optical modulator. Although not illustrated, a RF wiring between the driver IC 12 and the optical modulator chip 13 on the subcarrier 14 is also laid out with a differential line such as GSGSG or GSSG (S: signal, G: GND). When the RF differential line is bent, the high-frequency characteristics may deteriorate. Therefore, it is desirable that the position of the electrode pad of the driver and the position of the electrode pad of the modulator are aligned to be laid out and the RF differential line is formed linearly.

It is best that the high frequency wiring for connecting the driver IC 12 and the optical modulator chip 13 on the subcarrier 14 is formed on the outermost surface of the subcarrier 14 from the viewpoint of high-frequency loss. However, in a case where the high frequency signal line is formed on the outermost surface, there is a possibility that the underfill material overlie the high frequency signal line. It is difficult to control the degree of protrusion of the underfill material to the periphery of the chip with high accuracy. For this reason, asymmetry of a pair of the high frequency signal lines (for example, I+and I−) formed by the differential lines and variation between channels may occur, and high-frequency characteristics and transmission characteristics may be adversely affected.

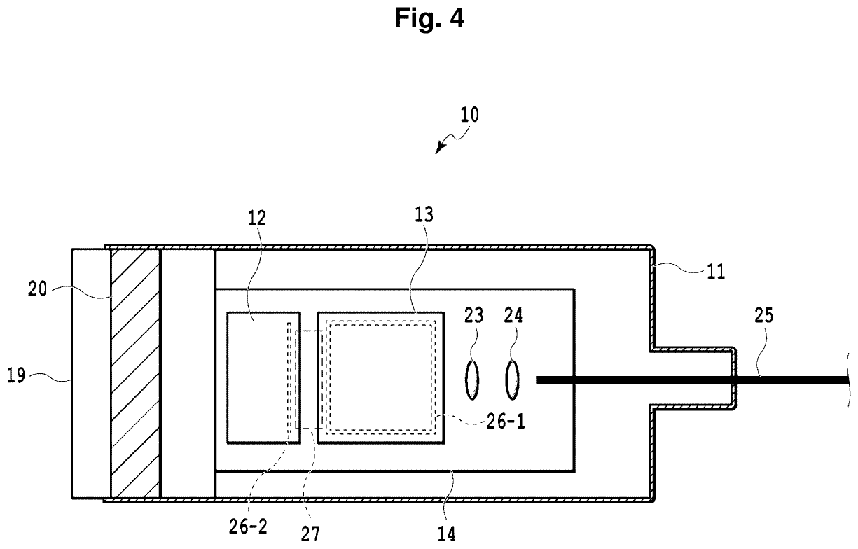

FIG. 4 is a top view illustrating a modification example of an implementation form of the optical transmitter of the present invention. This corresponds to a top view of a circuit plane inside a module when a housing 11 of the optical transmitter 10 illustrated in FIG. 2 is cut. In order to prevent an underfill material from flowing into a high frequency signal line of the subcarrier 14, grooves 26-1 and 26-2 are formed on the upper surface of the subcarrier 14 as indicated by dotted lines. The high frequency wiring of the subcarrier 14 is configured in a dotted line region 27 between the driver IC 12 and the optical modulator chip 13. In the driver IC 12 and the optical modulator chip 13, RF connection electrode pads are respectively formed around the driver IC and the optical modulator chip. By forming grooves on the upper surface of the subcarrier 14 at a position inside the electrode pads around these, an excess underfill material in the manufacturing process is accommodated in the grooves. The excess underfill material can be accommodated in the grooves without spreading over the IC and the high frequency wiring around the chip.

FIG. 4 illustrates an example in which the linear groove 26-2 is formed only on one side of the region 27 of the high frequency wiring in the driver IC 12, and a rectangular groove 26-1 is formed near four sides of the chip of the optical modulator chip 13. The shape of the groove is not limited to the configuration illustrated in FIG. 4, and can be changed according to the property of the underfill material, the form of the wiring on the subcarrier not to be affected, and the like. For example, in FIG. 4, the groove 26-2 of the driver IC 12 is provided only on one side on the optical modulator chip side, but may be formed in a rectangular shape around four sides of the driver IC. Furthermore, in addition to the configuration of FIG. 4, a linear groove may be added to one side of the driver IC 12 on the RF terrace side, that is, on the wiring board base 19 side. Moreover, in FIG. 4, the rectangular groove 26-1 is formed around four sides of the optical modulator chip 13, but the groove may be formed only on two sides of the driver IC side and the lens side to be described below.

The linear groove 26-2 of the driver IC 12 and a groove on the driver IC side in the rectangular groove 26-1 of the optical modulator chip 13 also serve as thermal separation grooves between the optical modulator chip and the driver IC. That is, a groove can be provided on the surface of the subcarrier 14 in the vicinity of at least one of the facing sides of the driver IC 12 and the optical modulator chip 13. In the optical transmitter of the present invention in which the two Peltier devices 17 and 18 operate via the common subcarrier 14, the groove described above can improve the independence of the temperature control, and the driver IC 12 can significantly reduce the high temperature and improve the high-frequency characteristics. Furthermore, in a case where the subcarrier 14 includes a multilayer substrate, the high frequency wiring can be formed in the inner layer, and thus a groove can also be formed in the region 27. By forming a groove between the driver IC 12 and the optical modulator chip 13 on at least one of the upper surface or the lower surface of the subcarrier 14, the groove can also serve as a thermal separation groove.

It is desirable to provide a groove for releasing the underfill material also on the subcarrier near the emission point of the waveguide of the optical modulator chip 13. Referring to FIG. 2 again, when the underfill material come out in the vicinity of the chip end surface on the lens side of the optical modulator chip 13, the underfill material adheres to the emission end face, and thus optical coupling with the lenses 23 and 24 may be deteriorated. The groove of one side of the rectangular groove 26-1 of the optical modulator chip 13 on the lens 23 side illustrated in FIG. 4 is also effective for avoiding such a trouble in the optical coupling.

In a case where the subcarrier 14 is formed to have a multilayer structure, it is possible to avoid the influence of the underfill material by configuring the high-frequency line in the inner layer of the subcarrier. Furthermore, when the high frequency wiring is configured in the inner layer, a groove can be formed on the upper surface of the subcarrier at an arbitrary position between the optical modulator chip and the driver IC. It goes without saying that sufficient consideration is required for disconnection of the inner layer wiring, an influence on the characteristic impedance, and the like. On the other hand, in a case where the high frequency wiring is designed with the same line impedance, the signal line width becomes narrow in the inner layer wiring due to the influence of the effective dielectric constant of the subcarrier. Moreover, since the influence of the dielectric loss tangent of the subcarrier is also received, it is desirable that a wiring pattern is present on the outermost surface of the subcarrier 14 when considering only the loss of the high-frequency line.

In the arrangement of the spatial optical components in FIG. 4, the lenses 23 and 24 are disposed on a side of the optical modulator chip 13 opposite to the driver IC 12. However, for example, at least one lens can also be disposed on the upper side or the lower side of the optical modulator chip 13 when viewed in the top view of FIG. 4. Furthermore, a PBC may be disposed on a side different from the driver IC. That is, the spatial optical component is mounted above the Peltier device 18 on a side different from a side of the chip of the optical modulator facing the driver IC 12. A groove for releasing an excess underfill material can be formed in the vicinity of a side of the chip of the optical modulator corresponding to the spatial optical component.

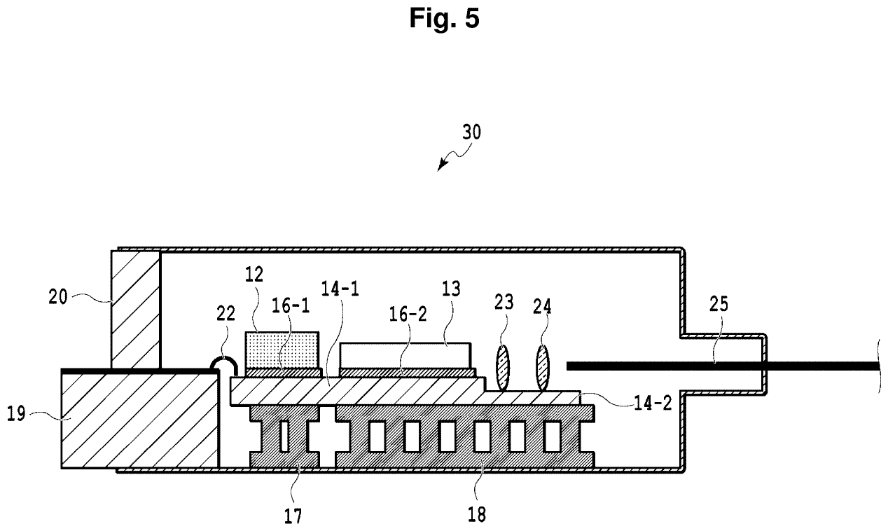

FIG. 5 is a side cross-sectional view illustrating another implementation form of the optical transmitter using the HB-CDM of the present invention.

An optical transmitter 30 of FIG. 5 is different from the configuration of the optical transmitter 10 of FIG. 2 in terms of the implementation form of the lenses 23 and 24. As described above, since the optical transmitter of the present invention is flip-chip mounted face down, the waveguide that emits the modulation output light of the optical modulator chip 13 is usually located near the lower surface of the chip close to the subcarrier 14 in the height direction. Furthermore, since the height of the Au pillar or the Cu pillar is usually about several 10 μm, the optical axis may deviate depending on the emission form of the modulation light and the type and size of lens, and the lens may not be mounted in a sufficient optical coupling state.

The optical transmitter 30 of FIG. 5 can facilitate optical coupling of the lens by changing the thickness of the subcarrier between the mounting region of the driver IC and optical modulator chip and the mounting region of the spatial optical component such as the lens. A subcarrier portion 14-2 that is the mounting region of the lenses 23 and 24 is thinner than a subcarrier portion 14-1 that is the mounting region of the driver IC 12 and the optical modulator chip 13. In the portion 14-2 on which the spatial optical components are mounted, it is desirable that the thickness of the subcarrier is equal to or larger than the radius of the lens. For example, assuming that the diameter of the lens is 500 μm, it is necessary to lower the subcarrier portion 14-2 from the upper surface by at least 250 μm to be thin. By controlling the thicknesses of the underfill materials 16-1 and 16-2 to be similar to the height of the Au pillar or the Cu pillar, it is possible to align the optical axis from the emission point of the optical modulation output light to the optical fiber 25. The height of the subcarrier can also be changed by using the subcarrier as a multilayer substrate to reduce the number of layers of the subcarrier portion 14-2 that is the mounting region of the lenses 23 and 24.

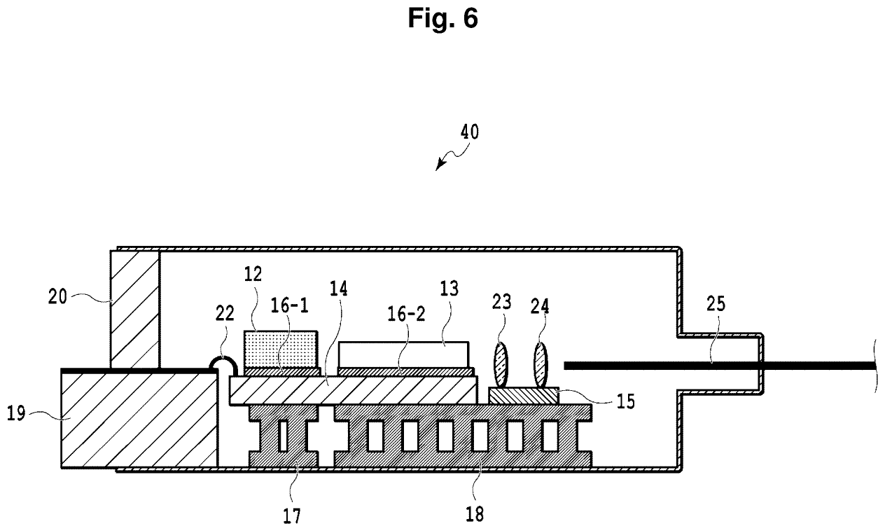

FIG. 6 is a side cross-sectional view illustrating still another implementation form of the optical transmitter using the HB-CDM of the present invention. In an optical transmitter 40 of FIG. 6, the subcarrier is divided into two, and the subcarrier 14 that is the mounting region of the driver IC and the optical modulator chip and a subcarrier 15 that is the mounting region of the spatial optical components such as the lenses are provided. With this configuration in which the subcarrier is divided into two, height adjustment of the lenses 23 and 24 is facilitated, and the optical axis from the emission point of the optical modulation output light to the optical fiber 25 can be aligned. Also in the optical transmitter 40, the temperature of the driver IC 12 and the temperature of the optical modulator chip 13 are controlled by the corresponding separate Peltier devices 17 and 18, respectively, via the single subcarrier 14, and the optical transmitter 40 has the same configuration as those of the optical transmitters 10 and 30 of FIGS. 2 and 5.

Furthermore, a configuration in which the optical members are directly mounted on the Peltier devices 17 and 18 also can be provided without the subcarrier 15 in FIG. 6.

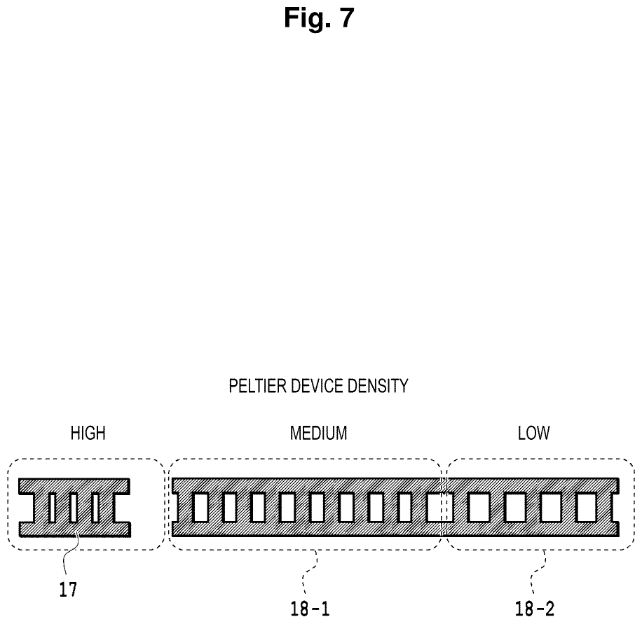

FIG. 7 is a diagram for describing density arrangement of the Peltier device in the optical transmitter of the present invention. In the Peltier device, a large number of n-type semiconductor elements and p-type semiconductor elements are disposed between the upper and lower metal surfaces to realize heat transfer between both surfaces as a whole. Therefore, the arrangement density of the semiconductor elements in the Peltier device can be set according to the heat generation amount of an object to be subjected to the temperature control. Considering the heat generation amount of each unit in the optical transmitter, the driver IC has the largest heat generation amount, and then the optical modulator chip and the spatial optical component are provided in this order. Specifically, the element densities of the Peltier devices are set such that the relationship of Mounting region of driver IC>Mounting region of optical modulator chip>Mounting region of spatial optical component is satisfied.

As illustrated in FIG. 7, the Peltier device 17 that controls the driver IC has the highest element density. Furthermore, in the Peltier device 18 that controls the optical modulator chip, a region 18-1 immediately under the optical modulator may have a medium density, and a region 18-2 for the spatial optical component or the like may have a low density.

As described above in detail, the optical transmitter of the present invention can suppress the temperature dependency of optical modulation output characteristics and realize a configuration and an implementation form of the optical transmitter excellent in high speed.

### INDUSTRIAL APPLICABILITY

The present invention can be used for an optical communication network.

1. An optical transmitter comprising:
an optical modulator;
a driver integrated circuit (driver IC) for supplying a modulation electrical signal for the optical modulator;
a first Peltier device for controlling a temperature of the optical modulator;
a second Peltier device for controlling a temperature of the driver IC; and
a subcarrier that including an electrical wiring between the optical modulator and the driver IC and being mounted on the first Peltier device and the second Peltier device,
wherein a chip of the optical modulator and the driver IC are flip-chip mounted face down, and
the temperature of the second Peltier device is set to be lower than the temperature of the first Peltier device.

2. The optical transmitter according to claim 1, wherein a distance between the driver IC and the chip of the optical modulator is 500 μm or more and 5 mm or less, and the electrical wiring on the subcarrier has a differential signal interface and is linearly formed.

3. The optical transmitter according to claim 1, wherein the temperature of the first Peltier device is set to 45±10° C., and
the temperature of the second Peltier device is set to 30±10° C.

4. The optical transmitter according to claim 1, wherein the optical modulator is made of InP,
at least one of an upper surface of the first Peltier device or an upper surface of the second Peltier device is made of aluminum nitride (AlN),
a gap between the subcarrier and the driver IC and the chip of the optical modulator generated by flip-chip mounting of the subcarrier, and the driver IC and the chip of the optical modulator is filled with an underfill material having thermal conductivity of 3 W/mK or more, and
the subcarrier has an outermost surface with flatness of 0.05 mm or less, the subcarrier including one or more layers of AlN.

5. The optical transmitter according to claim 1, wherein a spatial optical component is mounted above the first Peltier device on a side of the chip of the optical modulator opposite to the driver IC, and
a region of the subcarrier on which the spatial optical component is mounted has a thickness smaller than a thickness of a region of the subcarrier on which the optical modulator and the driver IC are mounted, or
a second subcarrier having a thickness smaller than the thickness of the subcarrier is further provided in the region in which the spatial optical component is mounted.

6. The optical transmitter according to claim 1, wherein a spatial optical component is mounted above the first Peltier device on a side different from a side of the chip of the optical modulator facing the driver IC, and
a groove is formed on a surface of the subcarrier in a vicinity of one side of the chip of the optical modulator on a side of the spatial optical component.

7. The optical transmitter according to claim 1, wherein a thermal separation groove is provided on an upper surface of the subcarrier in a vicinity of at least one of facing sides of the driver IC and the chip of the optical modulator or on at least one of an upper surface or a lower surface of the subcarrier between the driver IC and the chip of the optical modulator.

8. The optical transmitter according to claim 1, wherein the chip of the optical modulator and the driver IC are mounted in a package of a high-speed driver integrated optical modulator (HB-CDM),
a high frequency electrical wiring using a differential signal interface from an input unit of the package and an electrode pad for the modulation electrical signal are formed on an upper surface of the subcarrier, and
a difference in height between an upper surface of an RF terrace on which a radio frequency (RF) electrode pad of the input unit is formed and the upper surface of the subcarrier is 100 μm or less,
a gap between the RF terrace and the subcarrier in a circuit plane is 100 μm or less, and
the RF electrode pad of the RF terrace and the electrode pad of the subcarrier are connected by a wire.

9. The optical transmitter according to claim 1, wherein a spatial optical component is mounted above the first Peltier device on a side of the chip of the optical modulator opposite to the driver IC,
the first Peltier device and the second Peltier device respectively include an n-type semiconductor element and a p-type semiconductor element, and
in-plane densities of the n-type semiconductor element and the p-type semiconductor element are set such that the in-plane density of the second Peltier device, the in-plane density of a mounting region of the chip of the optical modulator on the first Peltier device, and the in-plane density of a mounting region of the spatial optical component on the first Peltier device are in descent order.
